(19) United States
(12) Patent Application Publication
(10) Pub. No.: US 2005/0187683 A1
(43) Pub. Date: Aug. 25, 2005

(54) Data communications control system

(75) Inventors: Koji Miki, Obu-city (JP); Makoto Aso, Nishikamo-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION

(21) Appl. No.: 11/019,288

(22) Filed: Dec. 23, 2004

(30) Foreign Application Priority Data
Feb. 9, 2004 (JP) 2004-31708

(51) Int. Cl. H03D 3/24; G06F 7/00

(52) U.S. Cl. 701/45; 701/46

(57) ABSTRACT

In a case where a dynamic range of an output signal from each of multiple sensors falls within ±D (LSB) in decimal numeration with a reference value centered, the reference value is set so that entire bits do not change between 1 and 0 when one of values within the dynamic range is added to the reference value. This decreases, within binary data from a data bus, the number of bits that change from 1 to 0 or from 0 to 1, further decreasing electric power consumption and enhancing a communications speed.

### CROSS REFERENCE TO RELATED APPLICATIONS

This application is based on and incorporates herein by reference Japanese Patent Application No. 2004-31708 filed on Feb. 9, 2004.

### FIELD OF THE INVENTION

The present invention relates to a data communications control system used for a vehicular air bag system or the like, In particular, relating to a data communications control system capable of decreasing electric power consumption for a waiting period.

### BACKGROUND OF THE INVENTION

In an SRS (Supplemental Restraint System) air bag used for an automobile or a vehicle, a G sensor continuously detects a collision deceleration of a vehicle body. A wave form of the detected collision deceleration is then converted by an A/D converter of an air bag ECU into a digital signal to be processed in a micro-computer. When the result from processing satisfies a predetermined condition, a power transistor turns on and then the air bag is expanded by a squib of an air bag module being power supplied.

Further, a safing sensor that closes and opens electric contact in a mechanical structure is disposed in parallel with a module ignition circuit, opening the contact in a normal state to shut off power supply to the module. When an impact of a setting level or more is applied, the contact is closed to turn on the power to the module.

Further, the power transistor and the safing sensor are separately disposing in one end of the module leading to the power source and the other end of the module leading to the earth, respectively. Therefore, the both ends of the module are cut off from the ECU, forming a both-ends-cut switch. This prevents mis-expansion even when one of in-vehicle wirings to the module short-circuits to a body or a power line.

It is preferable that the SRS air bag used in a vehicle detects at least a forward and backward directional collision deceleration and a vehicle-width directional collision deceleration at a collision timing. As described in Patent Document 1, more than one G sensor is usually disposed. When the multiple G sensors are disposed, each of the sensors is constructed to include a self-diagnostic circuit for detecting presence and absence of abnormality in the circuit at a starting timing.
Patent Document 1: JP-2002-145005 A

Each G sensor is continuously driven while the vehicle traveling, communicating with the air bag ECU. Power is thereby continuously consumed even in a normal waiting state even without, collision occurring. With the air bag system enhancing its functions, a communications speed from the G sensor and the number of G sensors have been increasing, so that power consumption is increased. Consequently, decreasing of the power consumption of the G sensor in the waiting state is a task to be achieved.

A typical G sensor exhibits variations in its output signal due to various factors. A dynamic range (an allowable variation quantity) that covers a given range with a reference value centered is set, so that the reference value of the center of the range is set to zero (0). When an output that exceeds the dynamic range is detected, the air bag ECU computes using signals from other sensors whether or not a collision occurs.

For instance, when an 8-bit binary data is transmitted from a data bus, a range of ±D (LSB) in decimal numeration from the reference value is recognized as a dynamic range. Here, D typically falls within five to ten. Further, when the data includes 8 bits, the reference value is typically set to approximately 128 in decimal numeration or approximately “1000000” in binary numeration. Here, when the reference value is set to “1000000,” occurrence of a variation of negative one (−1) in decimal numeration from the reference value results in transmitting of binary data of “01111111.” Further, when the reference value is set to “11111101,” occurrence of a variation of positive five (+5) in decimal numeration from the reference value results in transmitting of binary data of “00000010” as a result of carrying over to a parity bit. Here, entire bits of the binary data at once change. Power consumption therefore becomes significant when multiple sensors at once undergo these phenomena.

### SUMMARY OF THE INVENTION

It is an object of the present invention to provide a data communications control system with multiple sensors including a G sensor, the system which is capable of decreasing power consumption in a waiting state.

To achieve the above object, a data communications control system is provided with the following. A power source is included. A plurality of sensors is included for being driven by the power source. A data bus is included for transmitting, as binary data, an output signal of each of the plurality of sensors. A control unit is included for processing an input signal from the data bus and estimating, using a reference value to which a given value of the binary data is set, the binary data inputted from the data bus. Here, in a case where an allowable variation quantity of the output signal falls within a range of ±D (LSB) in decimal numeration with the reference value centered, the reference value is set so that entire bits of the reference value do not shift between 0 and 1 when a binary value within the range is added to the reference value.

In this structure, even when an output value varies within the dynamic range, the number of bits of the transmitted binary data that change between 0 and 1 is small. Thus, consumed electric current due to the change in bits becomes small, decreasing the power consumption. Further, a communications speed can be enhanced. Consequently, directing of the present invention to an air bag system with multiple G sensors enables increase of the number of G sensors and a communications speed, with the power consumption maintained at the same level. Further, this does not require significant increase in capacity of a power circuit of the air bag ECU.

### BRIEF DESCRIPTION OF THE DRAWINGS

The above and other objects, features, and advantages of the present invention will become more apparent from the following detailed description made with reference to the accompanying drawings. In the drawings:

FIG. 1 is an oblique perspective view of an automobile mounted with an air bag system of a data communications control system according to an embodiment of the present invention;

FIG. 2 is a block diagram of a data communications control system according to the embodiment; and

FIG. 3 is a flow chart diagram showing a control process of a control unit in a data communications control system according to the embodiment.

### DETAILED DESCRIPTION OF THE PREFERRED EMBODIMENTS

In a data communications control system of the present invention, for instance, it is supposed that there is a case where a dynamic range of an output signal from each of multiple sensors falls within ±D (LSB) in decimal numeration with a reference value centered. In this case, the reference value is set so that entire bits of the reference value do not change between 1 and 0 when one of values within the dynamic range is added to the reference value. This decreases, within one of binary values from a data bus, the number of bits that change from 1 to 0 or from 0 to 1, further decreasing consumed electric current and increasing a communications speed.

Here, the variation of the output signal from the sensor is often small, so that the variation within ±1 constitutes the majority. Therefore, the reference value is preferably set so that its entire bits do not change from 1 to 0 or from o to 1 when one of binary data within a range of ±1 in decimal numeration is added to the reference value. This can restrict power consumption from increasing.

The sensor can include a G sensor and pre-crash sensor without limitation. An output signal from a sensor is typically analog, so that the analog signal is converted to binary data using an A/D converter or the like to be inputted to a control unit via a data bus. Further, binary data transmitted from the respective sensors can be 4 bits, 8 bits, 16 bits, 32 bits etc., without limitation.

Hereinafter, comparative examples and an embodiment will be explained with reference to tables and figures.

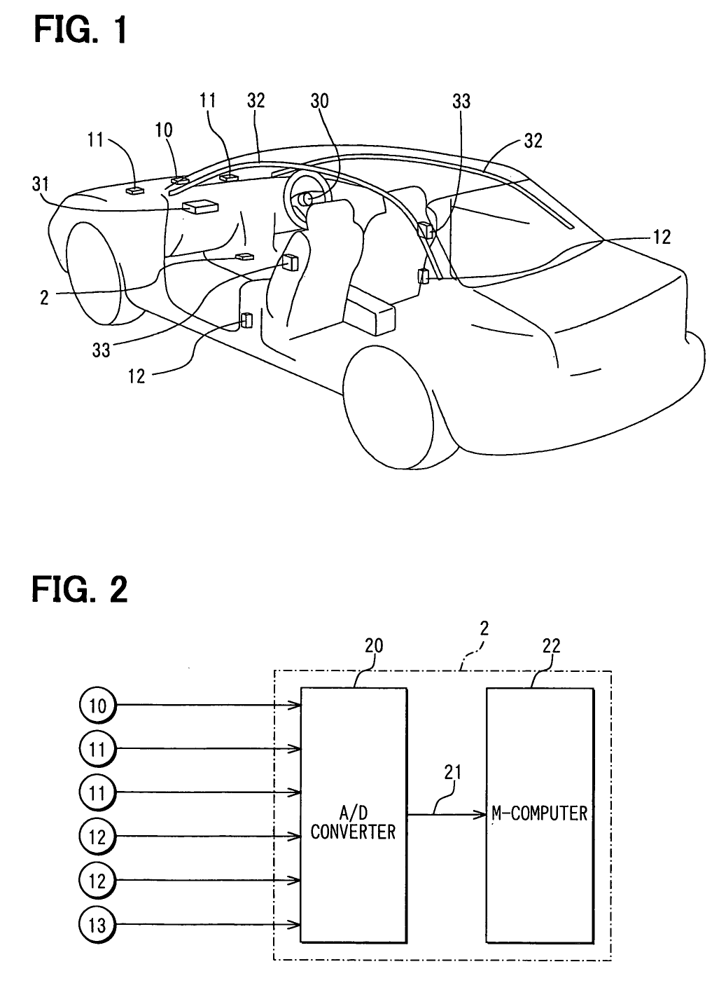

Each of data communications control systems of comparative examples and an embodiment is used for an air bag system in a vehicle. A compartment of the vehicle, as shown in FIG. 1, is equipped with a driver-seat air bag 30, an assistant-driver-seat air bag 31, a curtain air bag 32, and a side-collision air bag 33, all of which are expanded by expansion signals from an air bag ECU 2 disposed in a lower portion of the compartment. Further, a vehicle body includes a pre-crash sensor 10, front-collision G sensors 11, and side-collision G sensors 12, each of which inputs its output signal (electric current) to the air bag ECU 2. The air bag ECU 2 contains a preparatory G sensor 13 (not shown).

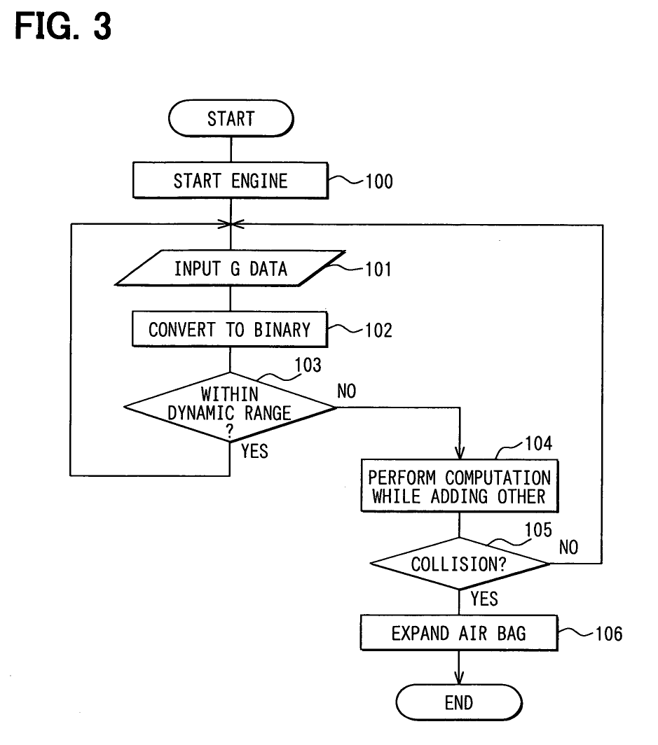

The respective sensors detect collision decelerations of a vehicle body by trigger signals from a trigger signal generating unit (not shown); then, output signals from the sensors are inputted to an A/D converter 20 as shown in FIG. 2. The output signals are thereby converted into 8-bit data in binary numeration to be inputted to a micro-computer 22 via a data bus 21. The operation will be explained with reference to a flow chart diagram in FIG. 3.

At Step 100, an engine is started, so that a given self-diagnosis circuit detects presence and absence of abnormality in each of the sensors and then trigger signals are successively generated from the trigger generating unit with short time intervals. Each sensor is triggered by the corresponding trigger signal to detect a collision deceleration of a vehicle body at this time point.

At Step 101, an output signal of each sensor is inputted as raw G data to the air bag ECU 2. At Step 102, the A/D converter 20 converts each output signal into 8-bit data in binary numeration to input it to the micro-computer 22 via the data bus 21 and a register.

At Step 103, the micro-computer 22 determines whether the inputted binary data falls within a predetermined range of a reference value ± allowable variation quantity (dynamic range). When the data is determined to falling within the predetermined range, the inputted data is determined to be zero G, returning to Step 101. By contrast, when the data is determined to falling outside the predetermined range, the process advances to Step 104, where the micro-computer 22 performs computation while adding output values from other sensors. At Step 105, it is determined whether a collision is occurring based on the computed value. When the collision is determined to be not occurring, the process returns to Step 101. By contrast, when the collision is determined to be occurring, the process advances to Step 106, where electric current is supplied to a squib of the air bag corresponding to each of collided portions. Each air bag corresponding to the collided portions is eventually expanded.

### COMPARATIVE EXAMPLE 1

In a data communications control system of a comparative example 1, for instance, “10000000” within 8-bit binary data from a certain G sensor is set to a reference value as zero G. Here, as shown in Table 1, a range of ±5 LSB in decimal numeration is defined as a dynamic range. That is, when data falls within ±5 LSB of the reference value “10000000,” the control unit determines that a collision deceleration in the corresponding G sensor is zero.

In this case, when an output value of a G sensor varies −1 LSB from the reference value “10000000,” a value in a register becomes “01111111.” That is, the entire bits are changed between 0 and 1. An electric current amount is thereby increased. As shown in Table 1, although the number of bits that change is small in the positive part from the reference value, the number of bits that change is six to eight in the negative part. Consequently, when this change in bits occurs in the entire G sensors, the total consumption power becomes large, so that power consumption in the waiting state naturally becomes large.

Therefore, when the number of G sensors is intended to be increased, increase in the capability of a power circuit of the air bag ECU 2 becomes indispensable, posing problems in the costs and spacing for equipment.

TABLE 1

| | | Number of bits that |
|---|---|---|
| | Binary | change from reference value |
| | 01111011 | 7 |
| | 01111100 | 6 |
| | 01111101 | 7 |
| | 01111110 | 7 |
| | 01111111 | 8 |
| Reference value | 10000000 | — |
| | 10000001 | 1 |
| | 10000010 | 1 |
| | 10000011 | 2 |
| | 10000100 | 2 |
| | 10000101 | 2 |

### COMPARATIVE EXAMPLE 2

In a data communications control system of a comparative example 2, for instance, “11111101” within 8-bit binary data from a certain G sensor is set to a reference value as zero G. Here, as shown in Table 2, a range of ±5 LSB in decimal numeration is defined as a dynamic range. That is, when data falls within ±5 LSB of the reference value “11111101,” the control unit determines that a collision deceleration in the corresponding G sensor is zero.

In this case when an output value of a G sensor varies +5 LSB from the reference value “11111101,” a value in a register becomes “00000010.” The entire bits change between 0 and 1. An electric current amount is thereby increased. As shown in Table 2, although the number of bits that change is small in the negative part from the reference value, the number of bits that change is six to eight in somewhere of the positive part. Consequently, when this change in bits occurs in the entire G sensors, the total consumption power becomes large, so that power consumption in the waiting state naturally becomes large.

Therefore, when the number of G sensors is intended to be increased, increase in the capability of a power circuit of the air bag ECU 2 becomes indispensable, posing problems in costs and spacing for equipment.

TABLE 2

| | | Number of bits that |
|---|---|---|
| | Binary | change from reference value |
| | 11111000 | 2 |
| | 11111001 | 1 |
| | 11111010 | 3 |
| | 11111011 | 2 |
| | 11111100 | 1 |
| Reference value | 11111101 | — |
| | 11111110 | 2 |
| | 11111111 | 1 |
| | 00000000 | 7 |
| | 00000001 | 6 |
| | 00000010 | 8 |

### Embodiment

By contrast, in a data communications control system of an embodiment of the present invention, for instance, “01111010” within 8-bit binary data from a certain G sensor is et to a reference value as zero G. Here, as shown in Table 3, a range of ±5 LSB in decimal numeration is defined as a dynamic range. That is, when data falls within ±5 LSB of the reference value “01111010,” the control unit determines that a collision deceleration in the corresponding G sensor is zero.

In the case, as shown in Table 3, even when an output value of a G sensor varies within the dynamic range from the reference value “01111010,” the number of bits that change becomes three in maximum. Therefore, compared with the comparative examples 1, 2 , consumption power can be significantly decreased, so that the number of G sensors can be thereby increased without requiring increase in the capability of a power circuit of the air bag ECU 2. Further, a communications speed can be also enhanced.

TABLE 3

| | | Number of bits that |
|---|---|---|
| | Binary | change from reference value |
| | 01110101 | 3 |
| | 01110110 | 1 |
| | 01110111 | 2 |
| | 01111000 | 1 |
| | 01111001 | 2 |
| Reference value | 01111010 | — |
| | 01111011 | 1 |
| | 01111100 | 2 |
| | 01111101 | 3 |
| | 01111110 | 1 |
| | 01111111 | 2 |

It will be obvious to those skilled in the art that various changes may be made in the above-described embodiments of the present invention. However, the scope of the present invention should be determined by the following claims.

1. A data communications control system comprising:
a power source;
a plurality of sensors that are driven by the power source;
a data bus that transmits, as binary data, an output signal of each of the plurality of sensors; and
a control unit that processes an input signal from the data bus and estimates, using a reference value to which a given value of the binary data is set, the binary data inputted from the data bus,
wherein, in a case where an allowable variation quantity of the output signal falls within a range of ±D (LSB) in decimal numeration with the reference value centered, the reference value is set so that entire bits of the reference value do not shift between 0 and 1 when a binary value within the range is added to the reference value.

2. The data communications control system of claim 1,
wherein the reference value is set so that entire bits of the reference value do not shift between 0 and 1 when a binary value within a range of ±1 in decimal numeration is added to the reference value.

3. The data communications control system of claim 1,
wherein the sensors includes a G sensor used in an air bag system for a vehicle, and
wherein, when a collision deceleration is regarded as zero G, the binary data within the range of the allowable variation quantity is transmitted.
